(19) United States
(12) Patent Application Publication
(10) Pub. No.: US 2021/0335640 A1
(43) Pub. Date: Oct. 28, 2021

(54) HOLDING DEVICE FOR HOLDING A CARRIER OR A COMPONENT IN A VACUUM CHAMBER, USE OF A HOLDING DEVICE FOR HOLDING A CARRIER OR A COMPONENT IN A VACUUM CHAMBER, APPARATUS FOR HANDLING A CARRIER IN A VACUUM CHAMBER, AND VACUUM DEPOSITION SYSTEM

(71) Applicants: Matthias HEYMANNS, Münster (DE); Applied Materials, Inc., Santa Clara, CA (US)

(72) Inventor: Matthias HEYMANNS, Münster (DE)

(21) Appl. No.: 16/478,045

(22) PCT Filed: Jul. 26, 2018
(86) PCT No.: PCT/EP2018/070291

§ 371 Date: Jul. 15, 2019

(51) Int. Cl. H01L 21/677; H01L 21/68; H01L 21/683; B25J 9/02; B25J 9/10; C23C 14/50; C23C 14/04; C23C 14/12

(52) U.S. Cl. CPC H01L 21/67709; H01L 21/67712; H01L 21/682; H01L 21/6831; B25J 15/0608; B25J 9/1005; C23C 14/50; C23C 14/042; C23C 14/12; B25J 9/023

(57) ABSTRACT

A holding device for holding a carrier or a component in a vacuum chamber is described. The holding device includes one or more electric controllable holding elements, a housing for at least partially housing the one or more electric controllable holding elements, the housing having a reception for the one or more electric controllable holding elements, a sealing for providing an air-tight sealing between the housing and the one or more electric controllable holding elements being arranged in the reception; and an air-tight connection for an electric supply line for the one or more electric controllable holding elements. Further, a method of producing a holding device, an apparatus for handling a carrier in a vacuum chamber, and a vacuum deposition system are described.

### TECHNICAL FIELD

Embodiments of the present disclosure relate to holding devices for holding a carriers or a components under vacuum conditions, methods of producing a holding device, apparatuses for handling a carrier, and vacuum deposition systems. In particular, embodiments of the present disclosure relate to holding devices and apparatuses configured for holding, moving or aligning a carrier in a vacuum chamber. Further, embodiments of the present disclosure particularly relate to vacuum deposition systems for depositing a material on a substrate carried by a carrier, wherein the substrate is aligned with respect to a mask before the deposition. Embodiments of the holding device, the apparatus for handling a carrier, and the vacuum deposition system are particularly configured for usage under vacuum conditions, e.g. for the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used for the manufacture of television screens, computer monitors, mobile phones, other hand-held devices and the like, e.g. for displaying information. An OLED device, such as an OLED display, may include one or more layers of an organic material situated between two electrodes that are deposited on a substrate.

During the deposition of a coating material on a substrate, the substrate may be held by a substrate carrier, and a mask may be held by a mask carrier in front of the substrate. A material pattern, e.g. a plurality of pixels, corresponding to an opening pattern of the mask can be deposited on the substrate, e.g. by material evaporation.

The functionality of an OLED device typically depends on the accuracy of the coating pattern and the thickness of the organic material, which should be within a predetermined range. For obtaining high-resolution OLED devices, technical challenges with respect to the deposition of evaporated materials need to be mastered. In particular, an accurate and smooth transport of a substrate carrier carrying a substrate and/or of a mask carrier carrying a mask through a vacuum system is challenging. Further, a precise handling of the substrate carrier with respect to the mask carrier under vacuum conditions is crucial for achieving high quality deposition results, e.g. for producing high-resolution OLED devices.

Accordingly, there is a continuing demand for improved holding devices for holding a carrier or a component under vacuum conditions, improved methods of producing a holding device suitable for vacuum usage, improved apparatuses for handling a carrier in a vacuum environment, and improved vacuum deposition systems.

### SUMMARY

In light of the above, a holding device for holding a carrier or a component in a vacuum chamber and a method of producing a holding device for holding a carrier in a vacuum chamber according to the independent claims are provided. Additionally, an apparatus for handling a carrier in a vacuum chamber, the apparatus including a holding device according embodiments described herein, is provided. Further, a vacuum deposition system including an apparatus for handling a carrier according embodiments described herein is provided. Further aspects, advantages, and features are apparent from the dependent claims, the description, and the accompanying drawings.

According to one aspect of the present disclosure, a holding device for holding a carrier or a component in a vacuum chamber is provided. The holding device includes one or more electric controllable holding elements and a housing for at least partially housing the one or more electric controllable holding elements. The housing includes a reception for the one or more electric controllable holding elements. Additionally, the holding device includes a sealing for providing an air-tight sealing between the housing and the one or more electric controllable holding elements being arranged in the reception. Further, the holding device includes an air-tight connection for an electric supply line for the one or more electric controllable holding elements.

According to a further aspect of the present disclosure, a use of a holding device according to any embodiments described herein for holding a carrier or a component in a vacuum processing system is provided.

According to another aspect of the present disclosure, a method of producing a holding device for holding a carrier in a vacuum chamber is provided. The method includes providing a housing for at least partially housing one or more electric controllable holding elements, providing the housing with a reception for the one or more electric controllable holding elements, providing the housing with an air-tight connection for an electric supply line for the one or more electric controllable holding elements, placing the one or more electric controllable holding elements into the reception, and providing an air-tight sealing between the housing and the one or more electric controllable holding elements being arranged in the reception.

According to a further aspect of the present disclosure, an apparatus for handling a carrier in a vacuum chamber is provided. The apparatus includes a vacuum chamber having a wall with an opening. Additionally, the apparatus includes a first driving unit arranged outside the vacuum chamber and configured to move a first driven part extending through the opening into the vacuum chamber. Further, the apparatus includes a first holding device attached to the first driven part in the vacuum chamber, the first driven part providing a first supply passage for supplying the first holding device with power and/or a control signal. The first holding device is a holding device according to any embodiments described herein.

According to a yet further aspect of the present disclosure, a vacuum deposition system is provided. The vacuum deposition system includes an apparatus for handling a carrier in a vacuum chamber according to any embodiments described herein. Further, the vacuum deposition system includes a deposition source provided in a deposition area of the vacuum chamber. The first holding device of the apparatus for handling the carrier in a vacuum chamber is configured for holding or moving the carrier in the deposition area.

Embodiments are also directed at apparatuses for carrying out the disclosed methods and include apparatus parts for performing the described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic perspective view of a holding device according to embodiments described herein;

FIG. 2 shows a schematic side view of a holding device according to embodiments described herein;

FIG. 3 shows a schematic perspective view of a holding device according to further embodiments described herein;

FIG. 4 shows a schematic sectional view of an apparatus for handling a carrier according to embodiments described herein;

FIG. 5 shows a schematic sectional view of an apparatus for handling a carrier according to further embodiments described herein;

FIG. 6 shows a schematic sectional view of a vacuum deposition system including an apparatus for handling a carrier according to embodiments described herein in a first position;

FIG. 7A shows the apparatus for handling the carrier of FIG. 6 in a second position;

FIG. 7B shows the apparatus for handling the carrier of FIG. 6 in a third position;

FIG. 8 shows a schematic sectional view of an apparatus for handling a carrier according to embodiments described herein;

FIG. 9 shows an exploded view of the apparatus for handling a carrier of FIG. 8;

FIG. 10 shows a perspective view of the apparatus for handling a carrier of FIG. 8; and

FIG. 11 is a flow diagram illustrating a method of producing a holding device for holding a carrier in a vacuum chamber according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

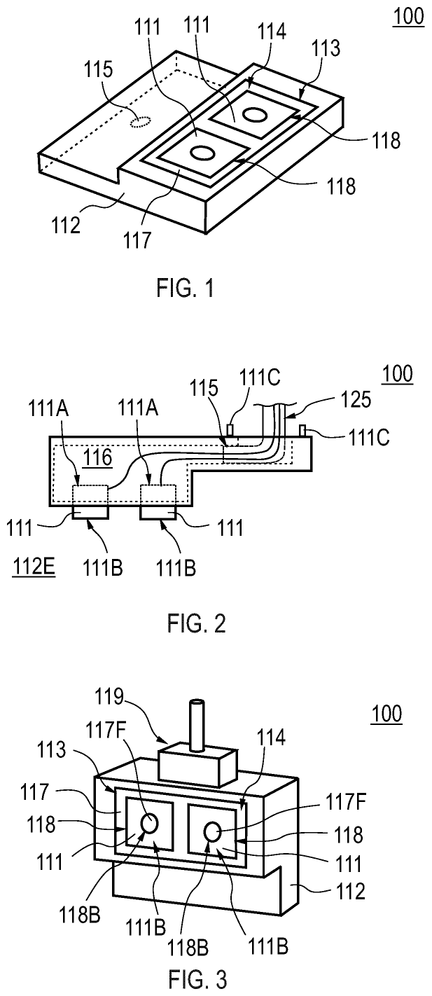

With exemplary reference to FIGS. 1 to 3, a holding device 100 for holding a carrier or a component in a vacuum chamber according to the present disclosure is described. According to embodiments which can be combined with any other embodiments described herein, the holding device 100 includes one or more electric controllable holding elements 111. Additionally, the holding device 100 includes a housing 112 for at least partially housing the one or more electric controllable holding elements 111. The housing has a reception 113 for the one or more electric controllable holding elements 111. Further, the holding device 100 includes a sealing 114 for providing an air-tight sealing between the housing and the one or more electric controllable holding elements 111 being arranged in the reception 113. Moreover, the holding device 100 includes an air-tight connection 115 for an electric supply line 125 for the one or more electric controllable holding elements 111. The electric supply line 125 may be configured for supply power and/or a control signal to the one or more electric controllable holding elements 111. Further, the electrical supply line may be configured as a sensor cable.

Accordingly, embodiments of the holding device as described herein are improved compared to conventional holding devices, particularly with respect to usage in vacuum environments. In particular, embodiments of the holding device as described herein have the advantage that non-vacuum compatible electric controllable holding elements (e.g. electro-permanent magnets (EPMs) and/or actuators for carrier alignment) can be employed in the holding device.

Before various further embodiments of the present disclosure are described in more detail, some aspects with respect to some terms used herein are explained.

In the present disclosure, a “holding device for holding a carrier” can be understood as a device configured for holding a carrier, e.g. a substrate carrier or a mask carrier, used during the processing of a substrate. A “holding device for holding a component” can be understood as a device configured for holding a component used during vacuum processing, e.g. a mask or a component of a carrier. Typically, the holding device is configured for usage in a vacuum environment, for example, in a vacuum chamber of a vacuum processing system, particularly a vacuum deposition system.

In the present disclosure, a “vacuum chamber” can be understood as a chamber configured for providing vacuum conditions inside the chamber. The term “vacuum” can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like). Accordingly, the vacuum chamber can be a “vacuum deposition chamber”, i.e. a vacuum chamber configured for vacuum deposition.

In the present disclosure, a “carrier” which can be held by the holding device can be a substrate carrier or a mask carrier. A “substrate carrier” can be understood as a carrier configured for carrying a substrate, particularly a large area substrate, in a vacuum chamber. A “mask carrier” can be understood as a carrier configured for carrying a mask, e.g. an edge exclusion mask or a shadow mask, in a vacuum chamber.

In the present disclosure, the term “substrate” may particularly embrace substantially inflexible substrates, e.g., a wafer, slices of transparent crystal such as sapphire or the like, or a glass plate. However, the present disclosure is not limited thereto, and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

According to embodiments described herein, the substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

In the present disclosure, the term “large area substrate” refers to a substrate having a main surface with an area of 0.5 m² or larger, particularly of 1 m² or larger. In some embodiments, a large area substrate can be GEN 4.5, which corresponds to about 0.67 m² of substrate (0.73×0.92 m), GEN 5, which corresponds to about 1.4 m² of substrate (1.1 m×1.3 m), GEN 7.5, which corresponds to about 4.29 m² of substrate (1.95 m×2.2 m), GEN 8.5, which corresponds to about 5.7 m² of substrate (2.2 m×2.5 m), or even GEN 10, which corresponds to about 8.7 m² of substrate (2.85 m×3.05 m). Even larger generations such as GEN 11 and GEN 12 and corresponding substrate areas can similarly be implemented. Half sizes of the GEN generations may also be provided in OLED display manufacturing. Further, the substrate thickness can be from 0.1 to 1.8 mm, particularly about 0.9 mm or below, such as 0.7 mm or 0.5 mm.

In the present disclosure, “one or more electric controllable holding elements” can be understood as one or more elements configured for providing a holding force for holding a carrier. The holding force can be understood as a force, particularly an attractive magnetic force, acting on a carrier as described herein. Further, some or all of the one or more electric controllable holding elements can, additionally or alternatively, be configured to move a carrier as described herein, particularly for performing an alignment of the carrier. In other words, a holding element configured to move a carrier can be used for aligning the carrier. The term “electric controllable” can be understood in that the holding elements can be controlled, e.g. activated or deactivated, by using electrical power or an electrical control signal. For example, one or more of the one or more electric controllable holding elements can be a magnetic mount configured to hold a carrier, particularly a magnetic mount with an electro-permanent magnet (EPM). According to another example, one or more of the one or more electric controllable holding elements can be an alignment device, particularly a piezo actuator, configured to move a carrier in at least one alignment direction.

In the present disclosure, a “housing for at least partially housing the one or more electric controllable holding elements” can be understood as a housing which is configured such that, in an assembled state of the holding device, a first portion of the one or more electric controllable holding elements is partially arranged inside the housing and a second portion of the one or more electric controllable holding elements extends out of the housing, e.g. through a reception or opening provided in the housing.

In the present disclosure, a “reception for the one or more electric controllable holding elements” can be understood as an opening provided in the housing, wherein the opening is seized and configured for receiving the one or more electric controllable holding elements.

In the present disclosure, a “sealing for providing an air-tight sealing” can be understood as one or more sealing elements arranged between the housing and the one or more electric controllable holding elements, wherein the interface between the housing and the one or more electric controllable holding elements as well as an interface between the one or more sealing elements and the one or more electric controllable holding elements are sealed in an air-tight manner.

In the present disclosure, an “air-tight connection for an electric supply line” can be understood as a portion or element of the holding device which is configured such that an electric supply line can be connected to the holding device in an air-tight manner. Herein, the term “air-tight” and the term “vacuum-tight” may be used interchangeably.

With exemplary reference to FIG. 2, according to some embodiments which can be combined with other embodiments described herein, the one or more electric controllable holding elements 111 are arranged in the reception 113 such that a first side 111A of the one or more electric controllable holding elements 111 faces an interior space 116 of the housing. As exemplarily shown in FIG. 2, a second side 111B of the one or more electric controllable holding elements 111 faces an exterior space 112E of the housing 112. Typically, the interior space 116 is an air-tight sealed space. Accordingly, when the holding device is used in a vacuum environment, beneficially an atmospheric environment, i.e. an environment having a pressure of approximately 1 bar, in the interior space 116 of the housing 112 can be maintained. As exemplarily shown in FIG. 2, typically a portion of the one or more electric controllable holding elements 111 extends out of the housing 112. In particular, the second side 111B of the one or more electric controllable holding elements 111 includes one or more active poles of an electro-permanent magnet (EPM), e.g. active poles of Roy Alloy. In the exemplary embodiments shown in FIGS. 1, 2 and 3, two electric controllable holding elements 111 being configured as EPMs are shown.

With exemplary reference to FIGS. 1 and 3, according to some embodiments which can be combined with other embodiments described herein, the sealing 114 includes a sheet element 117 with one or more reception openings 118 for the one or more electric controllable holding elements 111. Typically, the sheet element is made of a non-ferromagnetic metal, particularly stainless steel. The sheet element 117 may have a thickness T of 0.5 mm≤T≤4 mm, particularly 0.8 mm≤T≤3 mm, more particularly 1 mm≤T≤2.5 mm. For instance, the thickness T of the sheet element 117 can be T=1 mm±0.05 mm or T=2 mm±0.05. Typically, the planarity P of the sheet element 117 is P≤100 μm, particularly P≤50 μm.

According to some embodiments which can be combined with other embodiments described herein, the reception 113 of the housing, particularly the lateral edges of reception 113 are prepared for welding, particularly laser welding, the sheet element to the lateral edges of reception 113. Accordingly, the sheet element 117 can be connected to the housing by an air-tight connection. For instance, the air-tight connection can be a welded joint, particularly a laser welded joint. Typically, in an assembled state the exterior surface of the sheet element is coplanar with the exterior surface of the housing.

With exemplary reference to FIG. 3, according to some embodiments which can be combined with other embodiments described herein, holes 118B may be provided in the exterior surface of the one or more electric controllable holding elements 111, particularly in the exterior surface of the one or more active poles of the one or more electric controllable holding elements 111 being configured as electro-permanent magnets. The lateral edges of the holes 118B may be prepared for welding, particularly laser welding, further sheet elements 117F to the lateral inner edges of the holes 118B. The further sheet elements 117F may be separate sheet elements or part of the sheet element 117. Accordingly, the thickness and/or the planarity and/or the material of the further sheet elements 117F may correspond to the thickness and/or the planarity and/or the material of the sheet element 117.

According to some embodiments which can be combined with other embodiments described herein, the one or more electric controllable elements include at least one element selected from the group consisting of: a magnetic mount configured to hold the carrier and an alignment device. For example, the magnetic mount can include an electro-permanent magnet. Typically, the alignment device is configured to move the carrier in at least one alignment direction. For instance, the alignment device can be a piezo actuator.

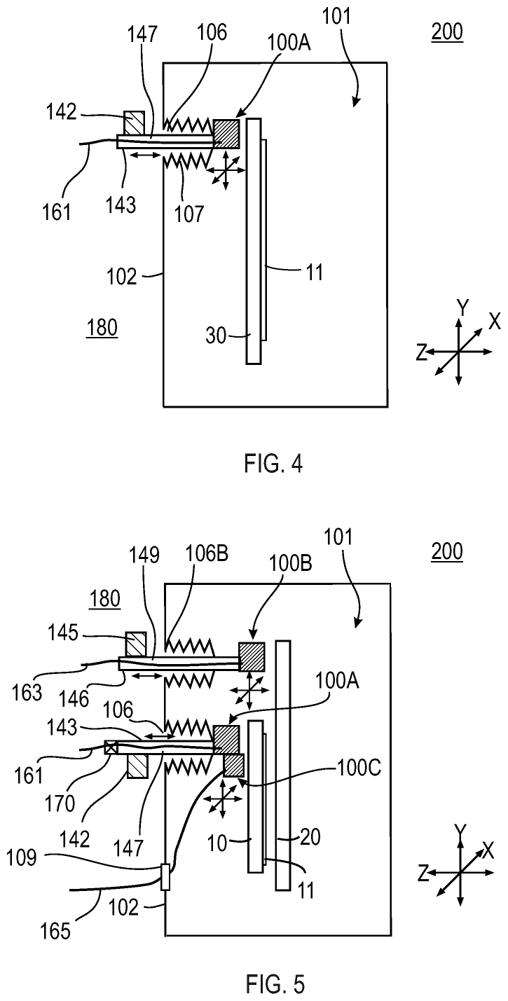

With exemplary reference to FIG. 2, according to some embodiments which can be combined with other embodiments described herein, connections pins 111C or connections bolts may be provided at the housing 112 for connecting the holding device to a driven part, e.g. a first driven part 143 or a second driven part 146, of an apparatus for handling a carrier in a vacuum chamber as exemplarily described with reference to FIGS. 4 and 5. Additionally or alternatively, with exemplary reference to FIG. 3, according to some embodiments which can be combined with other embodiments described herein, the housing 112 of the holding device 100 may further include a vacuum compatible connector 119 for connecting the holding device to a driven part of an apparatus for handling a carrier in a vacuum chamber.

In view of the above, it is to be understood that the holding device according to embodiments described herein is particularly well suited for being used in a vacuum environment. Accordingly, beneficially a use of a holding device according to any embodiments described herein for holding a carrier in a vacuum processing system can be provided.

With exemplary reference to FIG. 4, an apparatus 200 for handling a carrier in a vacuum chamber 101 according to the present disclosure is described. According to embodiments which can be combined with other embodiments described herein, the apparatus 200 includes a vacuum chamber 101 having a wall 102 with an opening 106. The vacuum chamber 101 is adapted to maintain a vacuum inside the vacuum chamber volume. An atmospheric environment 180, for example, an atmospheric environment with an atmospheric pressure of about 1 bar, may surround the vacuum chamber 101.

Additionally, the apparatus 200 includes a first driving unit 142 arranged outside the vacuum chamber 101. For example, the first driving unit 142 can include a linear actuator. The first driving unit 142 is configured to move a first driven part 143. For example, a linear movement may be transmitted to the first driven part 143 by the first driving unit 142. The first driving unit 142 may be a linear Z-actuator configured to move the first driven part 143 in a second direction Z. The first driven part 143 extends through the opening 106 into the vacuum chamber 101. In other words, the first driven part 143 passes from outside the vacuum chamber, e.g. from an atmospheric environment, through the wall 102 of the vacuum chamber 101. Accordingly, the first driven part 143 extending through the wall 102 is driven by the first driving unit 142 from outside the vacuum chamber 101. By driving the first driven part 143 from outside the vacuum chamber 101, maintenance and handling of the driving unit can be facilitated and the flexibility of the apparatus can be increased.

As exemplarily shown in FIG. 4, the opening 106 may be sealed with a flexible element 107, particularly with an axially deflectable element, e.g. a vacuum bellow, while allowing an axial movement of the first driven part 143. In particular, a portion of the first driven part 143 can be connected with the wall 102 of the vacuum chamber via the flexible element, such that the opening in the wall 102 through which the first driven part 143 extends is sealed in a vacuum-tight manner.

When the first driving unit 142 for driving the first driven part 143 can be arranged outside the vacuum chamber, i.e. in the atmospheric environment 180 under atmospheric pressure, a non-vacuum compatible driving unit can be used which is typically more cost-efficient and easier to handle than a vacuum-compatible driving unit. Further, an arbitrary type of a first driving unit 142, e.g. including an electric motor or a stepper motor can be provided. The generation of particles inside the vacuum chamber by the driving unit which may include mechanical bearings can be avoided. Accordingly, beneficially maintenance of the driving unit may be facilitated.

Further, the apparatus 200 includes a first holding device 100A attached to the first driven part 143, particularly an end portion of the first driven part 143, in the vacuum chamber 101. Accordingly, the first holding device 100A is provided in the interior of the vacuum chamber 101, i.e. in the vacuum environment of the vacuum chamber volume. For instance, the first holding device 100A may be attached to the first driven part 143 by one or more connecting elements. In some embodiments, the first holding device 100A is directly attached to the first driven part 143. Typically, the first holding device 100A is a holding device 100 according to any embodiments described herein, e.g. as described with reference to FIGS. 1 to 3.

Accordingly, it is to be understood that the first holding device 100A is configured to hold or to move the carrier 30. For example, the first holding device 100A may hold the carrier 30 during the deposition of a coating material on the substrate 11. In some embodiments, the first holding device 100A can be configured to hold a mask carrier configured to carry a mask. In another example, the first holding device 100A may move the carrier in at least one direction, particularly in at least one alignment direction. The at least one alignment direction can be a direction for aligning the carrier prior to a deposition process.

As the first holding device 100A is attached to the first driven part 143, the first holding device 100A can be moved together with the first driven part 143 by the first driving unit 142. When the first holding device 100A for holding or moving a carrier 30 is moved by a driving unit provided outside the vacuum chamber 101, maintenance and service of the respective components can be facilitated which are easily accessible from outside.

As exemplarily shown in FIG. 4, the first driven part 143 provides a first supply passage 147 for supplying the first holding device 100A with power and/or a control signal. In particular, the first supply passage 147 can be provided in the interior of the first driven part 143. Accordingly, the first supply passage 147 can be formed by an inner volume of the first driven part 143. For example, the first supply passage 147 can extend from a first end portion of the first driven part 143 to a second end portion of the first driven part 143. The second end portion of the first driven part 143 may be opposite the first end portion. Typically, one or more cables may extend through the first supply passage 147 to the first holding device 100A from outside the vacuum chamber, such that the first holding device 100A can be connected to a power supply and/or a controller provided outside the vacuum chamber.

Accordingly, beneficially the first holding device 100A is movable in a second direction Z via the first driving unit 142 and can be supplied with electrical power and/or signals. For example, the first holding device 100A may include an alignment device and/or a magnetic chuck (e.g. an electro-permanent magnet) which can be supplied with electrical power from outside the vacuum chamber through the first driven part 143.

With the first supply passage 147 provided by the first driven part 143, the first holding device 100A provided inside the vacuum chamber can be supplied from outside the vacuum chamber. As the first holding device 100A is attached to the first driven part 143, the first holding device 100A can also be moved together with the first driven part 143 by the first driving unit 142. Accordingly, the first driven part 143 may be used both for supplying and moving the first holding device 100A. Accordingly, a separate cable feedthrough in the vacuum chamber wall for supplying the first holding device 100A may be omitted. This may reduce the costs of an apparatus for handling a carrier.

According to some embodiments of the present disclosure, which can be combined with embodiments described herein, the first driven part includes a hollow shaft configured to feed at least one of a power cable, a signal cable, and a sensor cable to the first holding device 100A from outside the vacuum chamber. For illustration, FIG. 4 shows cable 161 which can be at least one of a power cable and a signal cable. For instance, the cable 161 can be connected to the first holding device 100A via an air-tight connection 115 as described herein, e.g. the air-tight connection 115 can be configured as a connection socket. For example, the air-tight connection may be provided at the housing 112 of the first holding device 100A. In some embodiments, the air-tight connection socket can be provided inside the housing of the first holding device 100A. As illustratively shown in FIG. 4, the cable 161 can extend into the interior of the first holding device 100A.

According to the present disclosure, “handling a carrier” can for example include operations such as moving a carrier, holding a carrier or aligning a carrier. In embodiments of the present disclosure, the carrier described herein can be a substrate carrier configured to carry a substrate or can be a mask carrier configured to carry a mask or a shield. FIG. 4 exemplarily shows the carrier 30 as a substrate carrier carrying a substrate 11.

Generally speaking, the carrier described herein can be a substrate carrier or a mask carrier. Hereinafter, the term “first carrier” specifies the carrier as a substrate carrier configured to carry a substrate. The term “second carrier” specifies the carrier as a mask carrier configured to carry a mask. It is to be understood that the first carrier may be alternatively a mask carrier configured to carry a mask or a shield.

Generally speaking, the carrier may be movable along a transport path by a carrier transport system. In some embodiments, the carrier may be contactlessly held during the transport, e.g. by a magnetic levitation system. In particular, the carrier transport system may be a magnetic levitation system configured to contactlessly transport the carrier along the transport path in the vacuum chamber. The carrier transportation system may be configured to transport the carrier into a deposition area of the vacuum chamber in which an alignment system and a deposition source are arranged.

A “substrate carrier” relates to a carrier device configured to carry a substrate 11 in the vacuum chamber 101. For example, the substrate carrier can be configured to carry the substrate along a first transport path in a first direction. The substrate carrier may hold the substrate 11 during the deposition of a coating material on the substrate 11. In some embodiments, the substrate 11 may be held at the substrate carrier in a non-horizontal orientation, particularly in an essentially vertical orientation, e.g. when moving the carrier, transporting the carrier along a transportation path, aligning the carrier and/or during a deposition process. In the embodiment depicted in FIG. 4, the substrate 11 is held at the carrier 30 in an essentially vertical orientation. For example, an angle between the substrate surface and the gravity vector may be less than 10 degrees, particularly less than 5 degrees.

For example, the substrate 11 may be held at a holding surface of the carrier during the transport through the vacuum chamber 101. The carrier may include a carrier body with a holding surface configured to hold the substrate 11, particularly in a non-horizontal orientation, more particularly in an essentially vertical orientation. In particular, the substrate 11 may be held at the carrier by a chucking device, e.g. by an electrostatic chuck (ESC) or by a magnetic chuck. The chucking device may be integrated in the carrier, e.g. in an atmospheric enclosure provided in the carrier.

A “mask carrier” as used herein relates to a carrier device configured to carry a mask for the transport of the mask along a mask transport path in the vacuum chamber. The mask carrier may carry the mask during transport, during alignment and/or during deposition on the substrate through the mask. In some embodiments, the mask may be held at the mask carrier in a non-horizontal orientation, particularly in an essentially vertical orientation during transport and/or alignment. The mask may be held at the mask carrier by a chucking device, e.g. a mechanical chuck such as a clamp, an electrostatic chuck or a magnetic chuck. Other types of chucking devices may be used which may be connected to or integrated in the mask carrier.

For instance, the mask may be an edge exclusion mask or a shadow mask. An edge exclusion mask is a mask which is configured for masking one or more edge regions of the substrate, such that no material is deposited on the one or more edge regions during the coating of the substrate. A shadow mask is a mask configured for masking a plurality of features which are to be deposited on the substrate. For instance, the shadow mask can include a plurality of small openings, e.g. an opening pattern with 10,000 or more openings, particularly 1,000,000 or more openings.

An “essentially vertical orientation” as used herein may be understood as an orientation with a deviation of 10 degrees or less, particularly 5 degrees or less from a vertical orientation, i.e. from the gravity vector. For example, an angle between a main surface of a substrate (or mask) and the gravity vector may be between +10 degrees and −10 degrees, particularly between 0 degrees and −5 degrees. In some embodiments, the orientation of the substrate (or mask) may not be exactly vertical during transport and/or during deposition, but slightly inclined with respect to the vertical axis, e.g. by an inclination angle between 0 degrees and −5 degrees, particularly between −1 degree and −5 degrees.

A negative angle refers to an orientation of a substrate (or mask) wherein the substrate (or mask) is inclined downward. A deviation of the substrate orientation from a gravity vector during deposition may be beneficial and might result in a more stable deposition process, or a face down orientation might be suitable for reducing particles on the substrate during deposition. However, an exactly vertical orientation (+/−1 degree) during transport and/or during deposition is also possible. In other embodiments, the substrates and masks may be transported in a non-vertical orientation, and/or the substrates may be coated in a non-vertical orientation, e.g. an essentially horizontal orientation.

According to some embodiments, which can be combined with other embodiments described herein, the first supply passage 147 provides a fluid connection between an interior of the first holding device 100A and an atmospheric environment 180 outside the vacuum chamber. For example, a fluid connection can be provided between the interior of the housing 112 of the first holding device 100A and the atmospheric environment.

When the interior of the first holding device 100A is adapted to be operated in an atmospheric environment, the first holding device 100A can be supplied through the first supply passage 147. For example, an electronic device or an electromagnet unit may not be adapted to be operated under vacuum conditions. In this case, the electromagnet unit would be provided in an atmospheric enclosure of the first holding device 100A, in particular a vacuum-tight enclosure, inside the vacuum chamber for operating properly. Accordingly, an atmospheric environment can be provided inside the first holding device 100A through the first supply passage 147. In this case, the first holding device 100A can be supplied by non-vacuum compatible equipment, e.g. non-vacuum compatible electrical cabling. Accordingly, beneficially acquisition costs and/or maintenance costs may be reduced. Further, particle generation in the vacuum chamber may be reduced as the electrical cabling, e.g. the cable 161, is not exposed to the vacuum environment inside the vacuum chamber 101. Further, a contamination of the vacuum environment in the vacuum chamber can be reduced or avoided by supplying the first holding device 100A through the first supply passage, e.g. when electronic devices arranged in the interior of the first holding device 100A are not vacuum-compatible.

With exemplary reference to FIG. 1, it is to be understood that the flexible element, in particular an axially expendable element, can be provided at the opening 106 of the wall 102, through which the first driven part 143 passes, in a vacuum-tight manner. The longitudinal axis of the axially expandable element may extend in a second direction Z. For example, an expandable element such as a bellow element can connect a portion of the first driven part with the wall 102, such that an opening in the wall 102 through which the first driven part 143 extends is closed in a vacuum-tight manner.

In embodiments of the present disclosure, which can be combined with embodiments described herein, the first driving unit can move the first driven part in the second direction Z. The second direction can be substantially perpendicular to the wall, e.g. the side wall, of the vacuum chamber and/or can be substantially perpendicular to the transport path of the carrier transport system.

According to some embodiments, which can be combined with embodiments described herein, the first holding device 100A can include a mount, particularly a magnetic mount configured to hold the carrier. The magnetic mount may hold the carrier by exerting an attractive magnetic force on the carrier. For instance, the magnetic mount can be an electro-permanent magnet. The cable 161 may be a power cable supplying an electromagnet of the mount with electric power and/or a signal cable configured to control the magnetic mount and/or a sensor cable. The electromagnet may be provided at an atmospheric pressure inside the housing of the first holding device 100A.

According to some embodiments, which can be combined with embodiments described herein, the first holding device 100A includes an alignment device. In particular, the alignment device can include a piezo actuator configured to move the carrier in at least one alignment direction. In some embodiments, the piezo actuator can be further configured to move the carrier in a second alignment direction transverse to the first alignment direction and/or in a third alignment direction transverse to the first and second alignment directions.

The term “aligning” refers to a positioning of the carrier exactly at a predetermined position in the vacuum chamber, particularly at a predetermined position relative to a second carrier. The carrier can be aligned in at least one alignment direction, particularly in two or three alignment directions which may be essentially perpendicular with respect to each other.

With exemplary reference to FIG. 5, according to some embodiments which can be combined with embodiments described herein, the apparatus 200 for handling a carrier in a vacuum chamber 101 can include a second driving unit 145 arranged outside the vacuum chamber. The second driving unit 145 can be configured to move a second driven part 146 extending through a further opening 106B into the vacuum chamber. The apparatus 200 can further include a second holding device 100B for holding or moving a carrier. Typically, the second holding device 100B is attached to the second driven part 146 in the vacuum chamber. In particular, the second driven part 146 can provide a second supply passage 149 for supplying the second holding device 100B.

As exemplarily shown in FIG. 5, according to some embodiments which can be combined with embodiments described herein, the apparatus 200 includes a first holding device 100A for holding or moving a first carrier 10 and a second holding device 100B for holding or moving a second carrier 20. The first holding device 100A is configured for holding or moving the first carrier 10. The second holding device 100B is configured for holding or moving the second carrier 20.

As can be seen by comparing FIG. 5 with FIG. 4, the apparatus shown in FIG. 5 includes similar features and elements to the apparatus shown in FIG. 4, such that with respect to the similar features and elements, reference can be made to the above explanations, which are not repeated here.

Hereinafter, an assembly including the first driving unit 142 and the first driven part 143 is sometimes referred to as a “first shifting device”. Similarly, an assembly including the second driving unit 145 and the second driven part 146 is sometimes referred to as a “second shifting device”. A system configured to align the first carrier 10, particularly with respect to the second carrier 20, is hereinafter sometimes referred to as an “alignment system”. The alignment system 130 includes the first driving unit 142 and the first driven part 143, wherein the first holding device 100A for holding or moving the first carrier is provided at the first driven part 143. The alignment system 130 may further include the second driving unit 145 and the second driven part 146 as well as the second holding device 100B for holding or moving the second carrier provided at the second driven part 146.

In FIG. 5, the second holding device 100B is attached to the second driven part 146. Similar to the first driven part 143, the second driven part 146 can provide a supply passage, i.e. a second supply passage 149 as shown in FIG. 5, for supplying the second holding device 100B, particularly with at least one of electrical power and signals.

In some embodiments, the second driven part 146 is configured to feed a supply element such as a cable to a holding device arranged inside the vacuum chamber, e.g. to a holding device provided at an end portion of the second driven part 146 inside the vacuum chamber. For example, the second holding device 100B for holding or moving the second carrier 20 can be supplied with electrical power from outside the vacuum chamber through the driven part 146.

In embodiments, the second driven part 146 includes a hollow shaft configured to feed at least one of a power cable, a signal cable, and a sensor cable to the second holding device 100B from outside the vacuum chamber 101.

According to some embodiments of the present disclosure, which can be combined with embodiments described herein, the apparatus 200 can include a vacuum feedthrough 170 in the first supply passage 147. The vacuum feedthrough 170 can be configured to separate a vacuum environment in an interior of the first holding device 100A from an atmospheric environment 180 outside the vacuum chamber 101.

According to some embodiments of the present disclosure, which can be combined with embodiments described herein, an interior of the first holding device can be configured for a vacuum environment, and a vacuum feedthrough is provided in a first supply passage. Additionally or alternatively, an interior of the second holding device is configured for an atmospheric environment, and the second supply passage provides a fluid connection between the interior of the second holding device and the atmospheric environment outside the vacuum chamber.

According to some embodiments, which can be combined with embodiments described herein, the first holding device 100A can be the alignment device configured to move the first carrier in at least one alignment direction, and the second holding device 100B can be the magnetic mount configured to hold the second carrier next to the first carrier. In particular, the first holding device 100A may include one or more piezoelectric actuators for aligning the first carrier 10 in one or more alignment directions, and the second holding device 100B may include a mount, particularly a magnetic mount, configured for holding the second carrier 20 at the second holding device 100B. The one or more piezoelectric actuators may be supplied with one or more cables extending through the first supply passage 147, and the magnetic mount for holding the second carrier may be supplied with one or more cables extending through the second supply passage 149.

According to some embodiments, which can be combined with embodiments described herein, the apparatus 200 can further include a third holding device 100C for holding or moving a carrier. In FIG. 5, the third holding device 100C is configured to hold the first carrier 10 at the first holding device 100A. In particular, the third holding device 100C may be a magnetic mount configured to hold the first carrier 10 at the first holding device 100A including an alignment device. In particular, the first holding device 100A may be an alignment device configured to align the first carrier 10 and the third holding device 100C may be configured to hold the first carrier 10 at the alignment device.

As exemplarily shown in FIG. 5, the apparatus 200 can include a cable feedthrough 109 in the wall 102 of the vacuum chamber 101 for supplying the third holding device 100C. The first driven part 143 and the second driven part 146 may extend through the same opening provided in a side wall of the vacuum chamber. The opening may be vacuum-sealed by a flexible element, particularly a bellow element.

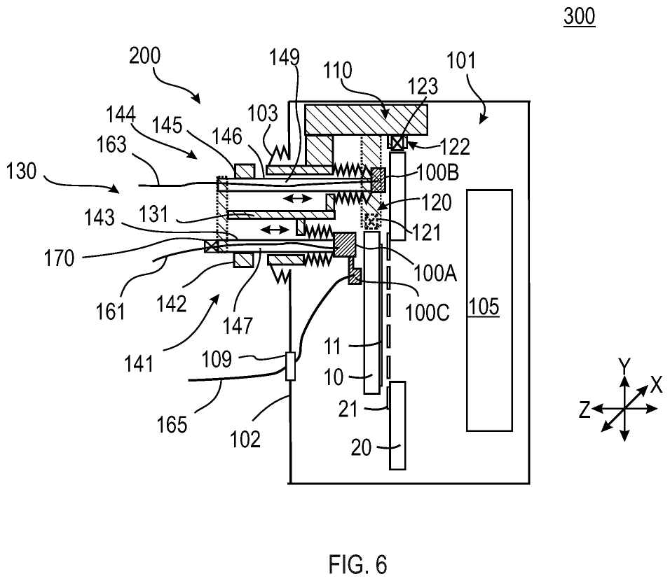

FIG. 6 shows a schematic sectional view of a vacuum deposition system 300 according to embodiments described herein. The vacuum deposition system includes an apparatus 200 for handling a carrier in a vacuum chamber 101 according to embodiments described herein.

As can be seen by comparing FIG. 6 with FIGS. 4 and 5, the apparatus shown in FIG. 6 includes similar features and elements as the apparatuses described with reference to FIGS. 4 and 5, such that with respect to the similar features and elements, reference can be made to the above explanations, which are not repeated here and only the differences will be discussed in the following.

In FIG. 6, the first holding device 100A is an alignment device, in particular an alignment device including at least one piezo actuator. The second holding device 100B is the magnetic mount configured to hold the second carrier 20. The magnetic mount includes an atmospheric enclosure, e.g. a housing 112 as described herein. In particular, the housing of the second holding device 100B is in fluid connection with the atmospheric environment 180 through the second supply passage 149. Accordingly, the second holding device 100B can be supplied from outside the vacuum chamber, while maintaining the atmospheric condition in the interior of the second holding device 100B.

As shown in FIG. 6, a cable 163, which can be a power cable, a signal cable, or a sensor cable, passes through the second supply passage 149 from outside the vacuum chamber to the interior of the second holding device 100B.

According to some embodiments, which can be combined with other embodiments described herein, the alignment device can be adapted to operate under vacuum conditions, i.e. the alignment device can be vacuum compatible. As exemplarily shown in FIG. 6, a vacuum feedthrough 170 in the first supply passage 147 may be provided, particularly when the first holding device 100A is an alignment device. Accordingly, the vacuum environment in the interior of the alignment device can be separated from the atmospheric environment 180 outside the vacuum chamber. Accordingly, the alignment device can be supplied by a power and/or signal cable and/or a sensor cable from outside, while the vacuum environment in the interior of the first holding device including an alignment device can be maintained.

In embodiments, the apparatus for handling a carrier can include a third holding device 100C for holding or moving the first carrier. In FIG. 6, the third holding device 100C is a magnetic mount, which may be similar to the second holding device including a magnetic mount as described above.

Typically, the third holding device 100C is configured to hold the first carrier 10. In particular, the third holding device 100C can be configured to hold the first carrier 10 at the first holding device 100A including an alignment device. More particularly, the third holding device 100C is connected to the first holding device 100A. Accordingly, the third holding device 100C can be moved together with the first holding device 100A by the first driving unit 142. Typically, the interior of the third holding device 100C is sealed in a vacuum-tight manner in order to maintain an atmospheric pressure in the interior of the third holding device 100C.

As described herein, the second holding device 100B can be supplied through the second supply passage 149. In embodiments, the third holding device 100C is supplied by a power cable and/or signal cable 165 and/or sensor cable fed through the cable feedthrough 109. The power cable and/or signal cable 165 and/or sensor cable can be fed through the cable feedthrough 109 into the interior of the vacuum chamber 101. The power cable and/or signal cable 165 and/or sensor cable can supply the third holding device 100C via a connection box, e.g. an air-tight connection 115 or a vacuum compatible connector 119 as described herein. The third holding device 100C and in particular the connection box are typically configured to seal the interior of the third holding device 100C, such that the power cable and/or signal cable 165 and/or sensor cable can be connected from the vacuum environment in the vacuum chamber 101 with the interior of the third holding device 100C while maintaining the atmospheric pressure in the interior of the third holding device 100C.

According to some embodiments, which can be combined with embodiments described herein, the power cable and/or signal cable 165 and/or sensor cable is an electrical cabling with a material for use in vacuum environments. For example, the power cable and/or signal cable 165 and/or sensor cable can be an in-vacuum cable such as a copper wire with vacuum compatible insulation. In particular, the power cable and/or signal cable 165 and/or sensor cable can be an electrical cabling with a low rate of outgassing.

Typically, the vacuum deposition system 300 is configured to deposit one or more materials on a substrate carried by the first carrier 10. Typically, the first holding device 100A is configured for holding or moving the carrier in the deposition area. A deposition source 105, particularly a vapor source configured to evaporate an organic material, may be provided in the vacuum chamber 101. The deposition source 105 may be arranged such that a material can be directed from the deposition source 105 toward the first carrier 10 that is mounted to the third holding device 100C. More specifically, the vacuum deposition system 300 includes a deposition source 105 provided in a deposition area of the vacuum chamber 101. Alternatively or additionally, the deposition source may include a rotatable distribution pipe provided with vapor outlets. The distribution pipe may extend essentially in a vertical direction and may be rotatable around an essentially vertical rotation axis. The deposition material may be evaporated in a crucible of the evaporation source and may be directed toward the substrate through the vapor outlets which are provided in the distribution pipe.

In particular, the deposition source 105 may be provided as a line source extending in an essentially vertical direction. The height of the deposition source 105 in the vertical direction may be adapted to a height of the vertically oriented substrate, such that the substrate can be coated by moving the deposition source 105 past the substrate in a first direction X.

In FIG. 6, the first carrier 10 is a substrate carrier which carries a substrate 11 to be coated, and the second carrier 20 is a mask carrier which carries a mask 21 to be arranged in front of the substrate 11 during deposition. The first carrier 10 and the second carrier 20 can be aligned relative to each other with the first shifting device 141, such that an evaporated material can be deposited exactly in a predetermined pattern on the substrate as defined by the mask.

In particular, the second carrier 20, which is mounted to the second holding device 100B, can be moved to a predetermined position in the second direction Z with the second shifting device 144. The first carrier 10 can be moved to a predetermined position adjacent to the second carrier 20 in the second direction Z with the first shifting device 141. The first carrier 10 can then be aligned with the first holding device including an alignment device in the alignment direction, particularly in the second direction Z, and/or optionally in one or more further alignment directions.

In some embodiments, which may be combined with other embodiments described herein, the alignment system 130 extends through a wall 102, in particular a side wall, of the vacuum chamber 101 and is flexibly connected to the side wall via a vibration isolation element 103 for providing a vibration isolation between the alignment system 130 and the side wall. The vibration isolation element may be an axially expandable element such as a bellow element.

According to some embodiments, which can be combined with embodiments described herein, the apparatus for handling a carrier can include a carrier transport system configured to transport the carrier in the vacuum chamber in a first direction X. The first driving unit can be configured to move the first driven part in a second direction Z transverse to the first direction. For example, the apparatus 200 shown in FIG. 6 includes a first carrier transport system 120 configured to transport a first carrier along the first transport path in the first direction X. The second direction Z may be essentially perpendicular to the first direction X along which the first carrier is transported by the first carrier transport system 120. After the transport of the first carrier in the first direction X, the first carrier can be mounted to the third holding device 100C and be shifted in the second direction Z away from the first transport path, e.g. toward the deposition source 105 or toward the second carrier 20 carrying a mask.

The first carrier transport system 120 may include a magnetic levitation system with at least one magnet unit 121, particularly with at least one actively controlled magnet unit configured to contactlessly hold the first carrier 10 at a guiding structure.

In some embodiments, the at least one alignment direction may essentially correspond to the second direction Z. Accordingly, the first carrier can be moved in the second direction Z by the first shifting device 141 and by the first holding device including an alignment device. The first shifting device 141 may be configured to perform a coarse positioning of the first carrier in the second direction Z, and the first holding device including an alignment device may be configured to perform a fine alignment of the first carrier in the second direction Z.

In some embodiments, the first holding device including an alignment device is configured to move the second holding device 100B in the second direction Z, and optionally in at least one of the first direction X and a third direction Y transverse to the first and second direction. The third direction Y may be an essentially vertical direction. Accordingly, the first carrier can be exactly positioned by the first holding device including an alignment device in the first direction X, the second direction Z and/or the third direction Y. In other embodiments, the first holding device including an alignment device can move the third holding device 100C only in two directions, e.g. in the second direction Z and in the third direction Y. In further embodiments, the first holding device including an alignment device can move the third holding device 100C only in one direction, particularly in the second direction Z.

The first holding device 100A and the third holding device 100C may be fixed to the driven part 143 of the first shifting device 141, such that the first holding device 100A and the third holding device 100C can be moved by the first shifting device 141 in the second direction Z. The first shifting device 141 includes a first driving unit 142 and a first driven part 143 that can be moved by the first driving unit 142 in the second direction Z. The first holding device 100A together with the third holding device 100C may be provided at the driven part 143, e.g. at a front end of the driven part 143 such as to be movable together with the driven part 143 in the second direction Z. The driven part 143 may comprise a linearly extending bar or arm extending from outside the vacuum chamber into the vacuum chamber in the second direction Z and can be moved by the first driving unit 142.

In some embodiments, which can be combined with other embodiments described herein, the first driving unit 142 of the first shifting device 141 may include a linear actuator configured to move the driven part 143 in the second direction Z by a distance of 10 mm or more, particularly 20 mm or more, more particularly 30 mm or more. For example, the first driving unit 142 may include a mechanical actuator, an electro-mechanical actuator, e.g. a stepper motor, an electric motor, a hydraulic actuator and/or a pneumatic actuator configured to move the driven part 143 in the second direction Z by a distance of 10 mm or more.

In some embodiments, which may be combined with other embodiments described herein, the first holding device may include at least one precision actuator, e.g. at least one piezo actuator, for providing a movement in the at least one alignment direction. In particular, the first holding device may include two or three piezo actuators configured for providing a movement in two or three alignment directions. For example, the piezo actuator of the first holding device may be configured to move the third holding device 100C in the second direction Z, and optionally in the first direction X and/or in the third direction Y. The first holding device may include an alignment device configured for a fine positioning (or fine alignment) of the third holding device 100C having the first carrier 10 mounted thereon in the at least one alignment direction. For example, the alignment device may be configured for a positioning of the first carrier with a sub-5-μm accuracy, particularly with a sub-μm accuracy. Accordingly, by having the first holding device including an alignment device together with the third holding device 100C provided at the driven part 143 of the first shifting device, a coarse positioning of the first mount can be performed by the first shifting device 141, and a fine positioning can be provided by the alignment device of the first holding device.

In some embodiments, which may be combined with other embodiments described herein, the third holding device 100C includes a magnetic chuck configured to magnetically hold the first carrier 10 at the third holding device 100C. For example, the third holding device 100C may include an electro-permanent magnet device configured to magnetically hold the first carrier. An electro-permanent magnet device can be switched between a holding state and a releasing state by applying an electric pulse to a coil of the electro-permanent magnet device. In particular, a magnetization of at least one magnet of the electro-permanent magnet device can be changed by applying the electric pulse.

The alignment system 130 shown in FIG. 6 may be (rigidly) fixed to a support 110 that is provided in the vacuum chamber, e.g. attached to the top wall of the vacuum chamber. In some embodiments, which may be combined with other embodiments described herein, the support 110 extends in the first direction X and carries or supports the at least one magnet unit 121 of the first carrier transport system 120. Accordingly, both the at least one magnet unit 121 and the alignment system 130 are fixed to the same mechanical support inside the vacuum chamber, such that vibrations or other movements of the vacuum chamber are transferred to the alignment system 130 and to the levitation magnets of the magnetic levitation system to the same extent. The alignment accuracy can be further improved and the carrier transport can be facilitated.

In some embodiments, the deposition source 105 may include a distribution pipe with a plurality of vapor openings or nozzles for directing the coating material into the deposition area. Further, the deposition source may include a crucible configured for heating and evaporating the coating material. The crucible may be connected to the distribution pipe such as to be in fluid communication with the distribution pipe.

In some embodiments, which may be combined with other embodiments described herein, the deposition source may be rotatable. For example, the deposition source may be rotatable from a first orientation in which the vapor openings of the deposition source are directed toward the deposition area to a second orientation in which the vapor openings are directed toward a second deposition area. The deposition area and the second deposition area may be located on opposite sides of the deposition source, and the deposition source may be rotatable by an angle of about 180 degrees between the deposition area and the second deposition area.

The first carrier transport system 120 may be configured for a contactless transport of the first carrier 10 in the vacuum chamber 101. For example, the first carrier transport system 120 may hold and transport the first carrier 10 by magnetic forces. In particular, the first carrier transport system 120 may include a magnetic levitation system.

In the exemplary embodiment of FIG. 6, the first carrier transport system 120 includes at least one magnet unit 121 arranged at least partially above the first carrier 10 and configured to carry at least a part of the weight of the first carrier 10. The at least one magnet unit 121 may include an actively controlled magnet unit configured to contactlessly hold the first carrier 10. The first carrier transport system 120 may further include a drive device configured to contactlessly move the first carrier 10 in the first direction X. In some embodiments, the drive device may be arranged at least partially below the first carrier 10. The drive device may include a drive such as a linear motor configured to move the first carrier by applying a magnetic force on the first carrier (not depicted).

With exemplary reference to FIG. 6, according to some embodiments which can be combined with other embodiments described herein, the alignment system 130 includes a main body 131 which is fixed to a support 110 provided inside the vacuum chamber. The first driving unit 142 of the first shifting device 141 and the second driving unit 145 of the second shifting device 144 may be fixed to the main body 131 of the alignment system 130. The main body 131 of the alignment system 130 may provide a feed-through through the wall 102 for the driven part 143 of the first shifting device and for the second driven part 146 of the second shifting device. The main body 131 of the alignment system 130 may be flexibly connected to the wall 102 of the vacuum chamber 101 via the vibration isolation element 103.

The main body 131 of the alignment system 130 may be fixed to the support 110. The support 110 may be (directly or indirectly) fixed to a top wall of the vacuum chamber and/or may be provided as a support rail or support girder which may extend in the first direction X. The top wall of the vacuum chamber is typically more strongly reinforced and less movable than the vertically extending side walls.

In some embodiments, which may be combined with other embodiments described herein, the first carrier transportation system 120 may be provided for transporting the first carrier along a first transport path in the first direction X, and a second carrier transportation system 122 may be provided for transporting the second carrier 20 along a second transport path parallel to the first transport path in the first direction X. The first carrier transportation system 120 and/or the second carrier transportation system 122 may be configured as magnetic levitation systems for a contactless carrier transport. In particular, the first carrier transportation system 120 may include at least one magnet unit 121, particularly an actively controlled magnet unit, for contactlessly holding the first carrier 10. The second carrier transportation system 122 may include at least one second magnet unit 123, particularly an actively controlled magnet unit, for contactlessly holding the second carrier 20. Typically, each magnetic levitation system includes a plurality of actively controlled magnet units which may be arranged along the first direction X at an essentially equal spacing. For example, the actively controlled magnet units may be fixed to the support 110.

In FIG. 6, the first carrier 10 and the second carrier 20 are contactlessly held by actively controlled magnet units of the first carrier transportation system 120 and the second carrier transportation system 122. The third holding device 100C is provided at a distance from the first carrier 10 in the second direction Z, and the second holding device 100B is provided at a distance from the second carrier 20 in the second direction Z.

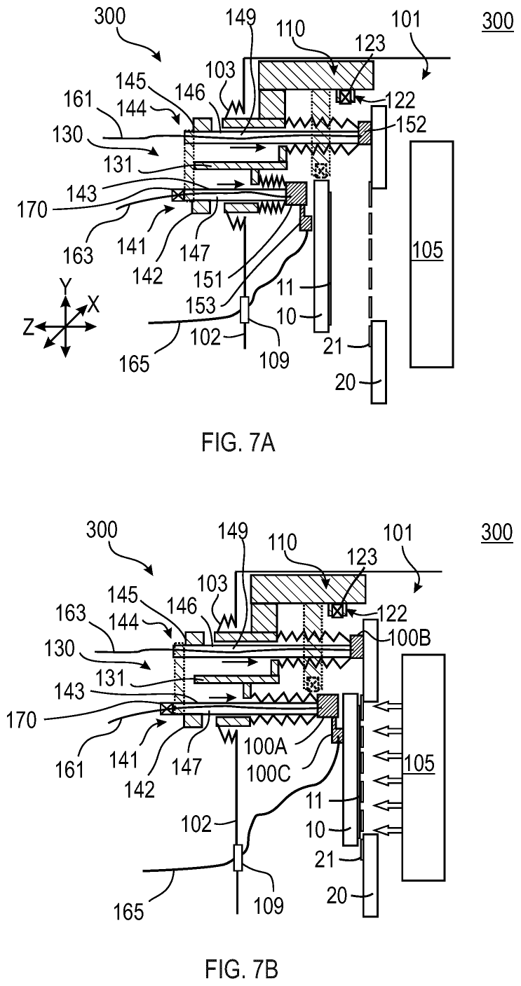

FIG. 7A shows the apparatus 200 of FIG. 3 in a second position. The second carrier 20 has been mounted to the second holding device 100B by moving the second holding device 100B to the second carrier 20 in the second direction Z and magnetically attaching the second carrier 20 to the second holding device 100B. The second carrier 20 is then moved by the second shifting device 144 in the second direction Z to a predetermined position, e.g. by a distance of 20 mm or more. In particular, the mask 21 that is carried by the second carrier 20 is positioned at a predetermined position facing the deposition source 105.

As is further depicted in FIG. 7A, the first carrier 10 carrying the substrate 11 is transported by the first carrier transport system 120 into the deposition area, and the third holding device 100C is mounted to the first carrier by moving the third holding device 100C to the first carrier 10 with the first shifting device 141.

As is schematically depicted in FIG. 7B, the first carrier 10 is then moved in the second direction Z toward the second carrier 20 by the first shifting device 141 until the substrate 11 is positioned close to the mask 21. Subsequently, the first carrier 10 is aligned in at least one alignment direction, particularly in the second direction Z, with the first holding device including an alignment device. The first carrier 10 may be positioned exactly at a predetermined position by the alignment device of the first holding device, e.g. including one or more piezo actuators.

Accordingly, beneficially the deposition as described herein is configured such that one or more materials can be deposited on the substrate 11 by the deposition source 105 through the openings of the mask 21, resulting in an accurate material pattern deposited on the substrate.

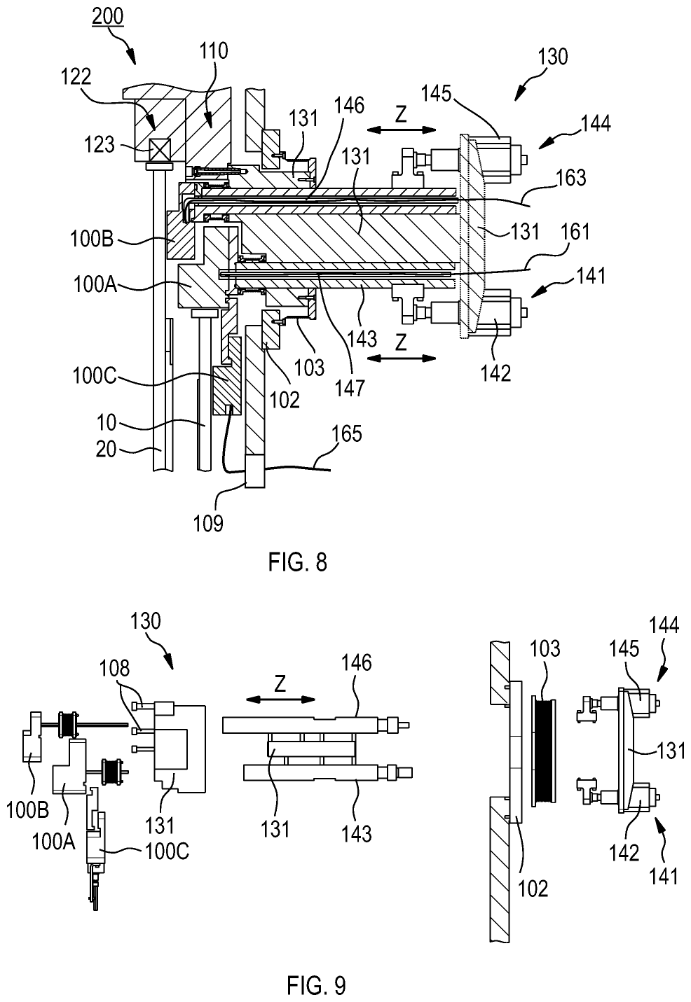

With reference to FIGS. 8, 9 and 10, some further optional aspects of the alignment system of the present disclosure are described.

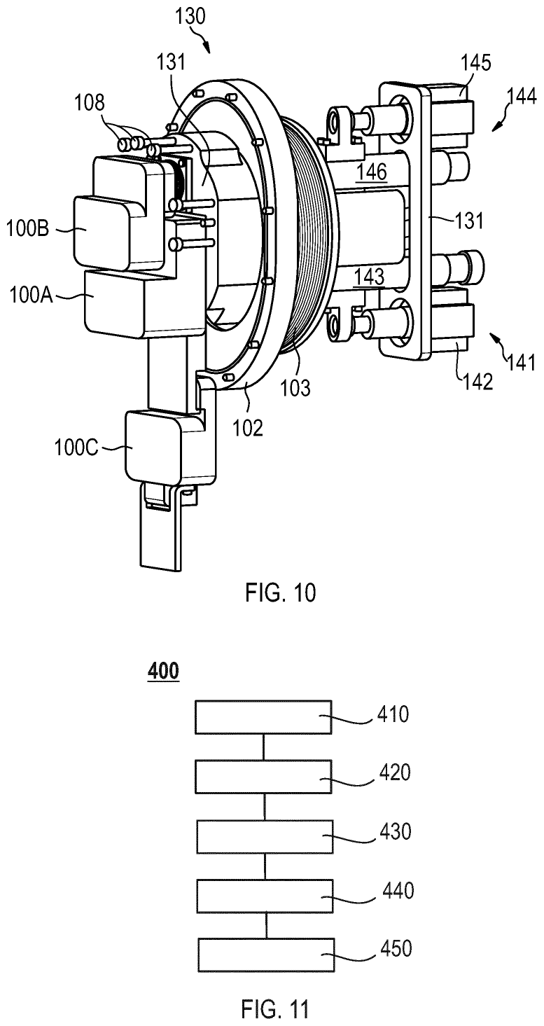

FIG. 8 shows a sectional view of an apparatus 200 for handling a carrier according to embodiments described herein. FIG. 9 shows an exploded view of the alignment system 130 of the apparatus 200 of FIG. 8. FIG. 10 shows a perspective view of the alignment system 130 of the apparatus 200 of FIG. 5.

As exemplarily shown in FIG. 8, a first driving unit 142 (e.g. a first Z-actuator) and a second driving unit 145 (e.g. a second Z-actuator) are provided outside the vacuum chamber 101. The first and the second driving unit are fixed to the main body 131. In some embodiments, the main body 131 is rigidly fixed to a support inside the vacuum chamber (not depicted in FIG. 8), e.g. via screws or bolts 108 (shown in FIG. 9), and flexibly connected to the wall 102.

The first driving unit 142 is configured to move the first driven part 143 which extends through the main body 131 into the vacuum chamber in the second direction Z, and the second driving unit 145 is configured to move the second driven part 146 which extends through the main body 131 into the vacuum chamber in the second direction Z. The second holding device 100B for mounting a first carrier to the alignment system is provided at a front end of the first driven part 143, and a third holding device 100C for mounting a second carrier to the alignment system is provided at a front end of the second driven part 146. Accordingly, the second holding device 100B and the third holding device 100C can be moved independently of each other in the second direction Z by the respective shifting device, in order to position the first and second carriers at respective predetermined positions in the second direction Z.

As exemplarily shown in FIG. 8, the second driven part 146 may protrude further into the vacuum chamber than the first driven part 143, such that the first carrier and the second carrier can be held adjacent to each other at the third holding device 100C and the second holding device 100B which are provided at the front ends of the driven parts.

The third holding device 100C is connected to the first driven part 143 via a first holding device 100A, typically including at least one piezo actuator. Accordingly, a fine positioning (or fine alignment) of the first carrier with respect to the second carrier can be performed by accurately positioning the third holding device 100C at a predetermined position with an alignment device of the first holding device 100A.

With exemplary reference to FIG. 10, according to some embodiments which can be combined with other embodiments described herein, a small gap 132 may be provided between the main body 131 of the alignment system 130 and the wall 102 of the vacuum chamber, such that the main body 131 does not move together with the wall 102, e.g. when the side wall vibrates or when the side wall moves due to a pressure change inside the vacuum chamber.

In some embodiments, the apparatus includes two or more alignment systems in the deposition area which are spaced apart from each other in the first direction X. Each alignment system may be configured in accordance with the alignment system 130 according to embodiments described herein. For example, a second mount of a first alignment system may be configured to hold an upper front part of the first carrier, and a first mount of a second alignment system may be configured to hold an upper rear part of the first carrier. Each alignment system may extend through the side wall of the vacuum chamber, such that the respective driving units of the respective shifting devices are positioned outside the vacuum chamber. Further, each alignment system may be flexibly connected to the side wall of the vacuum system via a respective vibration isolation element. In some embodiments, each alignment system is mechanically fixed to the same support that is provided inside the vacuum chamber, e.g. fixed to the top wall of the vacuum chamber.

The alignment device of the first alignment system may be configured to align the first carrier in the first direction X, the second direction Z, and the third direction Y, and the alignment device of the second alignment system may be configured to align the first carrier in the first direction Z and in the third direction Y. Further alignment systems with further alignment devices may be provided. Accordingly, the first carrier, being a three-dimensional object, can be positioned and rotated exactly to a predetermined translational and rotational position in the deposition area with respect to the second carrier.

With exemplary reference to the flow diagram shown in FIG. 11, a method 400 of producing a holding device 100 for holding a carrier in a vacuum chamber according to the present disclosure is described. According to embodiments which can be combined with any other embodiments described herein, the method 400 includes providing a housing 112 (represented by block 410 in FIG. 11) for at least partially housing one or more electric controllable holding elements 111. Additionally, the method 400 includes providing the housing 112 with a reception 113 (represented by block 420 in FIG. 11) for the one or more electric controllable holding elements 111. Further, the method 400 includes providing the housing 112 with an air-tight connection 115 (represented by block 430 in FIG. 11) for an electric supply line for the one or more electric controllable holding elements 111. Yet further, the method 400 includes placing the one or more electric controllable holding elements 111 into the reception 113 (represented by block 440 in FIG. 11). Moreover, the method 400 includes providing an air-tight sealing between the housing and the one or more electric controllable holding elements 111 being arranged in the reception 113 (represented by block 450 in FIG. 11).

According to some embodiments, which can be combined with other embodiments described herein, providing the air-tight sealing between the housing 112 and the one or more electric controllable holding elements 111 includes welding, particularly laser welding, a sheet element 117 to the housing 112.

According to some embodiments, which can be combined with other embodiments described herein, providing the housing 112 with the air-tight connection 115 includes providing a guiding hole for air-tightly guiding the electric supply line in the housing 112. Additionally or alternatively, providing the housing 112 with the air-tight connection 115 includes providing a vacuum compatible connector 119 for air-tightly connecting the holding device to a driven part of an apparatus for handling a carrier in a vacuum chamber. In particular, the driven part of the apparatus for handling a carrier can be a driven part of the apparatus 200 for handling a carrier according to any embodiments described herein.

According to some embodiments, which can be combined with other embodiments described herein, the method 400 further includes closing one or more machining holes provided in the housing by one or more sealing bolts. More specifically, typically all machining holes of the one or more machining holes provided during manufacturing of the holding device can be closed by sealing bolts.

In view of the above, it is to be understood that embodiments described herein are improved with respect to the prior art, particularly for manufacturing OLED devices in ultra clean vacuum (UCV) environments.

While the foregoing is directed to embodiments of the disclosure, other and further embodiments of the disclosure may be devised without departing from the basic scope thereof, and the scope thereof is determined by the claims that follow.

1. A holding device for holding a carrier or a component in a vacuum chamber, comprising:
one or more electric controllable holding elements;
a housing for at least partially housing the one or more electric controllable holding elements, the housing having a reception for the one or more electric controllable holding elements,
a sealing for providing an air-tight sealing between the housing and the one or more electric controllable holding elements being arranged in the reception; and
an air-tight connection for an electric supply line for the one or more electric controllable holding elements.

2. The holding device of claim 1, wherein the one or more electric controllable elements are arranged in the reception such that a first side of the one or more electric controllable elements faces an interior space of the housing and a second side of the one or more electric controllable elements faces an exterior space of the housing, wherein the interior space is air tight sealed.

3. The holding device of claim 1, wherein the sealing comprises a sheet element with one or more reception openings for the one or more electric controllable elements, the sheet element being connected to the housing by an air-tight connection.

4. The holding device of claim 3, the air-tight connection being a welded joint.

5. The holding device of claim 1, the one or more electric controllable holding elements comprising at least one element selected from the group consisting of: a magnetic mount configured to hold the carrier or the component, and an alignment device configured to move the carrier in at least one alignment direction.

6. The holding device of claim 1, the housing further comprising a vacuum compatible connector for connecting the holding device to a driven part of an apparatus for handling a carrier in a vacuum chamber or for connecting the holding device to a component in a vacuum chamber.

7. Use of a holding device for holding a carrier or a component in a vacuum processing system, the holding device comprising:
one or more electric controllable holding elements;
a housing for at least partially housing the one or more electric controllable holding elements, the housing having a reception for the one or more electric controllable holding elements;
a sealing for providing an air-tight sealing between the housing and the one or more electric controllable holding elements being arranged in the reception; and
an air-tight connection for an electric supply line for the one or more electric controllable holding elements.

8. Method of producing a holding device for holding a carrier or a component in a vacuum chamber, the method comprising:
providing a housing for at least partially housing one or more electric controllable holding elements;
providing the housing with a reception for the one or more electric controllable holding elements;
providing the housing with an air-tight connection for an electric supply line for the one or more electric controllable holding elements;
placing the one or more electric controllable holding elements into the reception; and
providing an air-tight sealing between the housing and the one or more electric controllable holding elements being arranged in the reception.

9. The method of claim 8, wherein providing the air-tight sealing between the housing and the one or more electric controllable holding elements comprises welding a sheet element to the housing.

10. The method of claim 8, wherein providing the housing with an air-tight connection comprises at least one of providing a guiding hole for air-tightly guiding the electric supply line in the housing and providing a vacuum compatible connector for air-tightly connecting the holding device to a driven part of an apparatus for handling a carrier in a vacuum chamber or for air-tightly connecting the holding device to a component in a vacuum chamber.

11. The method of claim 10, further comprising closing one or more machining holes provided in the housing by one or more sealing bolts.

12. An apparatus for handling a carrier in a vacuum chamber, comprising:
a vacuum chamber having a wall with an opening;
a first driving unit arranged outside the vacuum chamber and configured to move a first driven part extending through the opening into the vacuum chamber; and
a first holding device attached to the first driven part in the vacuum chamber, the first driven part providing a first supply passage for supplying the first holding device with power and/or a control signal, the first holding device comprising:
one or more electric controllable holding elements;
a housing for at least partially housing the one or more electric controllable holding elements, the housing having a reception for the one or more electric controllable holding elements;
a sealing for providing an air-tight sealing between the housing and the one or more electric controllable holding elements being arranged in the reception; and
an air-tight connection for an electric supply line for the one or more electric controllable holding elements.

13. The apparatus of claim 15, further comprising:
a second driving unit arranged outside the vacuum chamber and configured to move a second driven part extending through the opening into the vacuum chamber; and
a second holding device attached to the second driven part in the vacuum chamber, the second driven part providing a second supply passage for supplying the second holding device with power and/or a control signal, the second holding device comprising:
one or more electric controllable holding elements;
a housing for at least partially housing the one or more electric controllable holding elements, the housing having a reception for the one or more electric controllable holding elements;
a sealing for providing an air-tight sealing between the housing and the one or more electric controllable holding elements being arranged in the reception; and
an air-tight connection for an electric supply line for the one or more electric controllable holding elements.

14. The apparatus of claim 13, wherein the first holding device is an alignment device configured to move a first carrier in at least one alignment direction, and the second holding device is a magnetic mount configured to hold a second carrier next to the first carrier.

15. The apparatus of claim 14, further comprising a third holding device, wherein the third carrier holding device is configured to hold the first carrier at the alignment device, the third holding device comprising:
one or more electric controllable holding elements;
a housing for at least partially housing the one or more electric controllable holding elements, the housing having a reception for the one or more electric controllable holding elements;
a sealing for providing an air-tight sealing between the housing and the one or more electric controllable holding elements being arranged in the reception; and
an air-tight connection for an electric supply line for the one or more electric controllable holding elements.

16. The apparatus of claim 12, further comprising a carrier transport system configured to transport the carrier in the vacuum chamber in a first direction, wherein the first driving unit is configured to move the first driven part in a second direction transverse to the first direction.

17. A vacuum deposition system, comprising:
an apparatus for handling a carrier in a vacuum chamber, comprising:
a vacuum chamber having a wall with an opening;
a first driving unit arranged outside the vacuum chamber and configured to move a first driven part extending through the opening into the vacuum chamber; and
a first holding device attached to the first driven part in the vacuum chamber, the first driven part providing a first supply passage for supplying the first holding device with power and/or a control signal, the first holding device comprising:
one or more electric controllable holding elements;
a housing for at least partially housing the one or more electric controllable holding elements, the housing having a reception for the one or more electric controllable holding elements;
a sealing for providing an air-tight sealing between the housing and the one or more electric controllable holding elements being arranged in the reception; and
an air-tight connection for an electric supply line for the one or more electric controllable holding elements; and
a deposition source provided in a deposition area of the vacuum chamber, wherein the first holding device is configured for holding or moving the carrier in the deposition area.

18. The holding device of claim 3, the air-tight connection being a laser welded joint.

19. The holding device of claim 1, the one or more electric controllable holding elements comprising at least one element selected from the group consisting of: a magnetic mount with an electropermanent magnet, and a piezo actuator configured to move the carrier in at least one alignment direction.

20. The method of claim 8, wherein providing the air-tight sealing between the housing and the one or more electric controllable holding elements comprises laser welding a sheet element to the housing.
